(19) United States
(12) Patent Application Publication
(10) Pub. No.: US 2024/0266368 A1
(43) Pub. Date: Aug. 8, 2024

(54) SEMICONDUCTOR DEVICE INCLUDING LOW-VOLTAGE DEVICE AND MIDDLE-VOLTAGE DEVICE, DISPLAY DRIVING DEVICE INCLUDING THE SAME, AND METHOD OF MANUFACTURING SEMICONDUCTOR DEVICE

(71) Applicant: LX SEMICON CO., LTD., Daejeon (KR)

(72) Inventor: Kee Joon CHOI, Daejeon (KR)

(73) Assignee: LX SEMICON CO., LTD., Daejeon (KR)

(21) Appl. No.: 18/435,203

(22) Filed: Feb. 7, 2024

(30) Foreign Application Priority Data
Feb. 8, 2023 (KR) 10-2023-0016809

(51) Int. Cl. H01L 27/12

(52) U.S. Cl. CPC H01L 27/1251; H01L 27/1288; H01L 27/1237

(57) ABSTRACT

A semiconductor device according to the present disclosure includes a low-voltage device configured to receive a first level voltage and a first middle-voltage device configured to receive a second level voltage higher than the first level voltage. The low-voltage device includes a low-voltage well region, the first middle-voltage device includes a 1-1^{st} middle-voltage well region and a 1-2^{nd} middle-voltage well region, and the low-voltage well region and the 1-1^{st} middle-voltage well region have a first well concentration with respect to a first conductivity type impurity.

This application claims the benefits of Korean Patent Application No. 10-2023-0016809, filed on Feb. 8, 2023, which is hereby incorporated by reference in its entirety as if fully set forth herein.

### BACKGROUND

### Field

The present disclosure relates to a semiconductor device including a low-voltage device and a middle-voltage device, a display driving device including the same, and a method of manufacturing the semiconductor device.

### Discussion of the Related Art

With rapid growth of the semiconductor industry, technological advances have produced generations of semiconductor devices, where each generation has smaller and more complex circuits than the previous generation. In the course of integrated circuit (IC) evolution, functional density (i.e., the number of interconnected devices per chip area) has generally increased while geometric size (i.e., the smallest component (or line) that can be created using a manufacturing process) has decreased. This scaling-down process generally provides benefits by increasing production efficiency and lowering associated costs. However, these advantages have also increased the complexity of semiconductor devices and a process of manufacturing the same.

### SUMMARY

The present disclosure has been made to solve the above problems, and a technical task of the present disclosure is to provide a semiconductor device including a low-voltage device and a middle-voltage device, which is capable of securing device characteristics according to respective functions and reducing manufacturing costs, a display driving device including the same, and a method of manufacturing the semiconductor device.

A semiconductor device according to an embodiment of the present disclosure includes a low-voltage device configured to receive a first level voltage and a first middle-voltage device configured to receive a second level voltage higher than the first level voltage. The low-voltage device includes a low-voltage well region, the first middle-voltage device includes a 1-1^{st} middle-voltage well region and a 1-2^{nd} middle-voltage well region, and the low-voltage well region and the 1-1^{st} middle-voltage well region have a first well concentration with respect to a first conductivity type impurity.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a diagram showing a display device to which a display driving device according to an embodiment of the present disclosure is applied;

FIG. 2 is a block diagram of the display driving device according to an embodiment of the present disclosure;

FIG. 3 is a cross-sectional diagram of a low-voltage device and a first middle-voltage device according to an embodiment of the present disclosure;

FIG. 4 is a cross-sectional diagram of a second middle-voltage device according to an embodiment of the present disclosure;

FIG. 5 is a flowchart of a semiconductor device manufacturing process according to an embodiment of the present disclosure; and

FIGS. 6A to 6G are diagrams showing a semiconductor device manufacturing process according to an embodiment of the present disclosure.

### DETAILED DESCRIPTION

Reference will now be made in detail to the exemplary embodiments of the present disclosure, examples of which are illustrated in the accompanying drawings. Wherever possible, the same reference numbers will be used throughout the drawings to refer to the same or like parts. In the following description, when a configuration and a function known to those skilled in the art are irrelevant to the essential configuration of the present disclosure, a detailed description thereof will be omitted. The terms described in the specification should be understood as follows.

Advantages and features of the present disclosure and methods for achieving the same will be made clear from embodiments described below in detail with reference to the accompanying drawings. The present disclosure may however, be embodied in many different forms, and should not be construed as being limited to the embodiments set forth herein. Rather, these embodiments are provided so that this disclosure will be thorough and complete, and will fully convey the scope of the disclosure to those skilled in the art. Furthermore, the present disclosure is only defined by scopes of the claims.

In the drawings for explaining the exemplary embodiments of the present disclosure, for example, the illustrated shape, size, ratio, angle, and number are given by way of example, and thus, are not limited to the disclosure of the present disclosure. Throughout the present specification, the same reference numerals designate the same constituent elements. In addition, in the following description of the present disclosure, a detailed description of known functions and configurations incorporated herein will be omitted when it may make the subject matter of the present disclosure rather unclear.

The terms “comprises,” “includes,” and/or “has”, used in this specification, do not preclude the presence or addition of other elements unless used along with the term “only”. The singular forms are intended to include the plural forms as well, unless the context clearly indicates otherwise.

In the interpretation of constituent elements included in the various embodiments of the present disclosure, the constituent elements are interpreted as including an error range even if there is no explicit description thereof.

In the description of the various embodiments of the present disclosure, when describing positional relationships, for example, when the positional relationship between two parts is described using “on”, “above”, “below”, “next to”, or the like, one or more other parts may be located between the two parts unless the term “directly” or “closely” is used.

In the description of the various embodiments of the present disclosure, when describing temporal relationships, for example, when the temporal relationship between two actions is described using “after”, “subsequently”, “next”, “before”, or the like, the actions may not occur in succession unless the term “directly” or “just” is used therewith.

It may be understood that, although the terms “first”, “second”, etc. may be used herein to describe various elements, these elements are not to be limited by these terms. These terms are merely used to distinguish one element from another. Therefore, in the present specification, an element indicated by “first” may be the same as an element indicated by “second” without exceeding the technical scope of the present disclosure, unless otherwise mentioned.

The term “at least one” should be understood as including all possible combinations which can be suggested from one or more relevant items. For example, the meaning of “at least one of a first item, a second item, or a third item” may be each one of the first item, the second item, or the third item and also be all possible combinations that can be suggested from two or more of the first item, the second item, and the third item.

The respective features of the various embodiments of the present disclosure may be partially or entirely coupled to and combined with each other, and various technical linkages and modes of operation thereof are possible. These various embodiments may be performed independently of each other, or may be performed in association with each other.

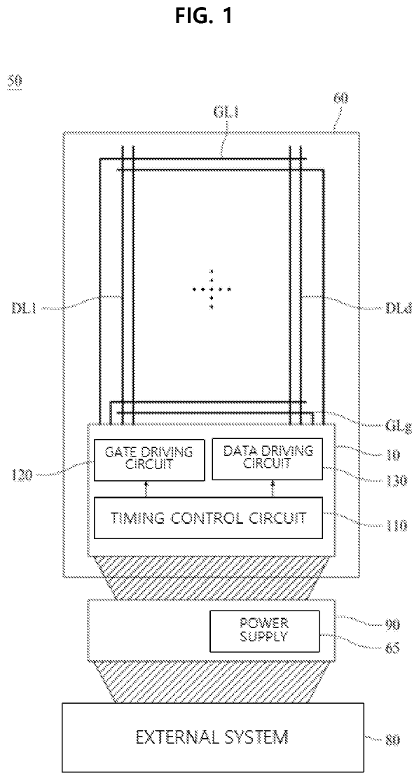

Hereinafter, a display device including a display driving device according to an embodiment of the present disclosure will be described in detail with reference to FIG. 1. FIG. 1 is a diagram showing a display device to which a display driving device according to an embodiment of the present disclosure is applied.

A display device 50 according to the present disclosure includes a display panel 60, a power supply 65, and an external system 80. In addition, the display device 50 according to the present disclosure includes a display driving device 10.

The display panel 60 may be an organic light-emitting panel in which an organic light-emitting device is formed, or may be a liquid crystal panel in which a liquid crystal is formed. That is, all types of panels that are currently used may be applied as the display panel 60 applied to the present disclosure. Thus, the display device according to the present disclosure may also be an organic light-emitting display device, a liquid crystal display device, and various other types of display devices. However, hereinafter, for convenience of description, a liquid crystal display device will be described as an example of the present disclosure.

When the display panel 60 is a liquid crystal panel, a plurality of data lines DL1 to DLd, a plurality of gate lines GL1 to GLg crossing the data lines, a plurality of thin-film transistors (TFTs) formed at intersections of the data lines and the gate lines, a plurality of pixel electrodes for charging data voltages to pixels, and a common electrode for driving a liquid crystal charged in a liquid crystal layer together with the pixel electrodes are formed on a lower glass substrate of the display panel 60, and the pixels are disposed in the form of a matrix due to an intersection structure of the data lines and the gate lines.

A black matrix (BM) and a color filter are formed on an upper glass substrate of the display panel 60. A space between the lower glass substrate and the upper glass substrate is filled with the liquid crystal.

A liquid crystal mode of the display panel 60 applied to the present disclosure may be implemented as a twisted-nematic (TN) mode, a vertical alignment (VA) mode, an in-plane switching (IPS) mode, a fringe-field switching (FFS) mode, or any other type of liquid crystal mode. In addition, the display device 50 according to the present disclosure may be implemented in any form such as a transmissive liquid crystal display, a semi-transmissive liquid crystal display, or a reflective liquid crystal display.

The display panel 60 displays an image in response to a gate signal and a source signal output from the display driving device 10.

The power supply 65 is mounted on a main board 90 and supplies voltages to drive the display panel 60, the display driving device 10, and the external system 80. In this case, in addition to the power supply 65, various circuit elements may be mounted on the main board 90.

The power supply 65 generates voltages according to driving voltages of the circuits included in the display driving device 10 and supplies the voltages to the circuits. In this case, the driving voltages of the circuits of the display driving device 10 may include a first level voltage, a second level voltage, and a third level voltage. The first level voltage may be a low voltage, the second level voltage may be a middle voltage higher than the low voltage, and the third level voltage may be a high voltage. For example, the first level voltage may range from 0.9 V to 1.8 V, the second level voltage may range from 7 V to 9 V, and the third level voltage may be 10 V or more.

In addition, the power supply 65 supplies power for driving of the display panel 60 to the display panel 60 so that the display panel 60 operates.

The display driving device 10 may include a timing control circuit 110 for controlling a gate driving circuit 120 and a data driving circuit 130 formed in the display panel 60, the gate driving circuit 120 for controlling signals input to the gate lines, and the data driving circuit 130 for controlling signals input to the data lines formed in the display panel 60.

In this case, although the display driving device 10 is illustrated in FIG. 1 as being mounted on the display panel 60, this is merely exemplary. The display driving device 10 may be separated from the display panel 60 and mounted on a separate board.

In addition, the timing control circuit 110, the gate driving circuit 120, and the data driving circuit 130 constituting the display driving device 10 may be formed as a single semiconductor device, or may be individually provided.

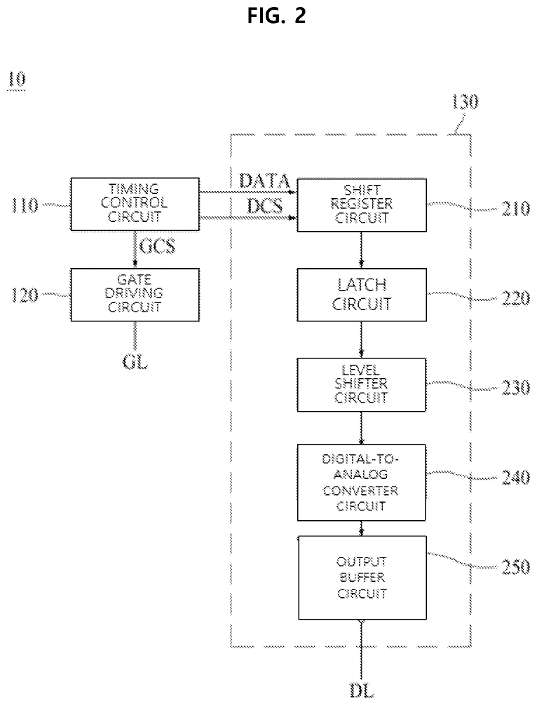

Hereinafter, the display driving device according to an embodiment of the present disclosure will be described in detail with reference to FIG. 2. FIG. 2 is a diagram showing circuits constituting the display driving device according to an embodiment of the present disclosure.

As shown in FIG. 2, the timing control circuit 110 supplies a gate control signal GCS to the gate driving circuit 120 to control the gate driving circuit 120. In detail, the timing control circuit 110 receives first image data and timing signals from the external system 80. The timing control circuit 110 generates the gate control signal GCS for control of the gate driving circuit 120 according to the timing signal, and generates a data control signal DCS for control of the data driving circuit 130.

In one embodiment, the timing control circuit 110 generates the gate control signal GCS including a gate start pulse (GSP), a gate shift clock (GSC), and a gate output enable (GOE) signal.

In one embodiment, the timing control circuit 110 generates the data control signal DCS including a source start pulse (SSP), a source sampling clock (SSC), and a source output enable (SOE) signal.

The timing control circuit 110 transmits the gate control signal GCS to the gate driving circuit 120, and transmits the data control signal DCS to the data driving circuit 130.

The timing control circuit 110 arranges the first image data received from the external system 80. In detail, the timing control circuit 110 generates second image data by arranging the first image data according to the structure and characteristics of the display panel 60.

The timing control circuit 110 transmits the second image data to the data driving circuit 130.

The gate driving circuit 120 outputs gate signals, which are synchronized with source signals generated by the data driving circuit 130, to the gate lines according to timing signals generated by the timing control circuit 110. In detail, the gate driving circuit 120 outputs the gate signals, which are synchronized with the source signals, to the gate lines according to the gate start pulse, the gate shift clock, and the gate output enable signal generated by the timing control circuit 110.

The gate driving circuit 120 includes a gate shift register circuit and a gate level shifter circuit. In this case, the gate shift register circuit may be formed directly on a TFT array substrate of the display panel 60 through a gate-in-panel (GIP) process. In this case, the gate driving circuit 120 supplies the gate start pulse and the gate shift clock signal to the gate shift register circuit formed on the TFT array substrate through the GIP process.

The data driving circuit 130 converts the second image data into a source signal according to the timing signal generated by the timing control circuit 110. In detail, the data driving circuit 130 converts the second image data into the source signal according to the source start pulse, the source sampling clock, and the source output enable signal. The data driving circuit 130 outputs the source signal corresponding to one horizontal line to the data lines at every one horizontal period in which the gate signal is supplied to the gate line.

In this case, the data driving circuit 130 may receive a gamma voltage from a gamma voltage generator (not shown), and may convert the second image data into the source signal using the gamma voltage. To this end, as shown in FIG. 2, the data driving circuit 130 includes a shift register circuit 210, a latch circuit 220, a level shifter circuit 230, a digital-to-analog converter circuit 240, and an output buffer circuit 250.

The shift register circuit 210 receives the source start pulse and the source sampling clock from the timing control circuit 110, and sequentially shifts the source start pulse according to the source sampling clock to output a sampling signal. The shift register circuit 210 transmits the sampling signal to the latch circuit 220.

The latch circuit 220 sequentially samples and latches the second image data by a predetermined unit according to the sampling signal. The latch circuit 220 transmits the latched second image data to the level shifter circuit 230.

The level shifter circuit 230 amplifies the level of the latched second image data. In detail, the level shifter circuit 230 amplifies the level of the second image data to a level that allows the digital-to-analog converter circuit 240 to be driven. The level shifter circuit 230 transmits the second image data of which the level is amplified to the digital-to-analog converter circuit 240.

The digital-to-analog converter circuit 240 converts the second image data into the source signal, which is an analog signal. The digital-to-analog converter circuit 240 transmits the source signal, which is a converted analog signal, to the output buffer circuit 250.

The output buffer circuit 250 outputs the source signal to the data lines. In detail, the output buffer circuit 250 buffers the source signal according to the source output enable signal generated by the timing control circuit 110, and outputs the buffered source signal to the data lines.

According to an embodiment of the present disclosure, the shift register circuit 210 and the latch circuit 220 may receive the first level voltage, which is a low voltage, and the level shifter circuit 230 and the digital-to-analog converter circuit 240 may receive the second level voltage, which is a middle voltage. That is, the shift register circuit 210 and the latch circuit 220 include a low-voltage device LV Device that receives the first level voltage LV_VDD, which is a low voltage, and the level shifter circuit 230 and the digital-to-analog converter circuit 240 include a first middle-voltage device MV Device1 or a second middle-voltage device MV Device2 that receives the second level voltage MV_VDD, which is a middle voltage. Accordingly, the display driving device 10 according to the embodiment of the present disclosure may include a semiconductor device including the low-voltage device LV Device, the first middle-voltage device MV Device1, and the second middle-voltage device MV Device2.

In this case, the level shifter circuit 230 and the digital-to-analog converter circuit 240 commonly receive the second level voltage MV_VDD, but perform different functions from each other. Thus, the device included in the level shifter circuit 230 and the device included in the digital-to-analog converter circuit 240 are required to have different electrical characteristics from each other. However, implementation of electrical characteristics corresponding to respective functions increases manufacturing costs. Therefore, in the embodiment of the present disclosure, a process of manufacturing the low-voltage device is used to manufacture some of elements of the first middle-voltage device MV Device1 and the second middle-voltage device MV Device2, whereby the electrical characteristics required for the device included in the level shifter circuit 230 and the electrical characteristics required for the device included in the digital-to-analog converter circuit 240 are implemented, and manufacturing costs of semiconductor devices may be reduced.

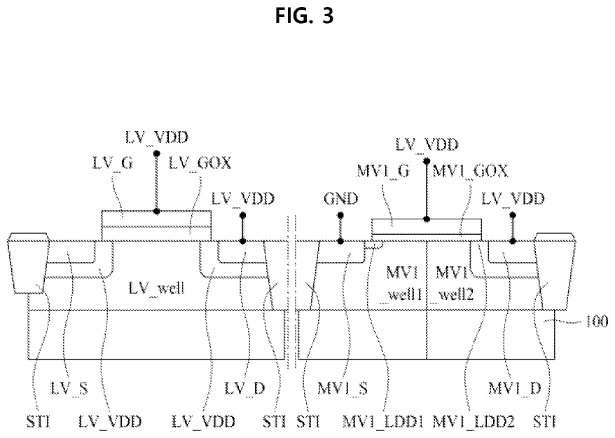

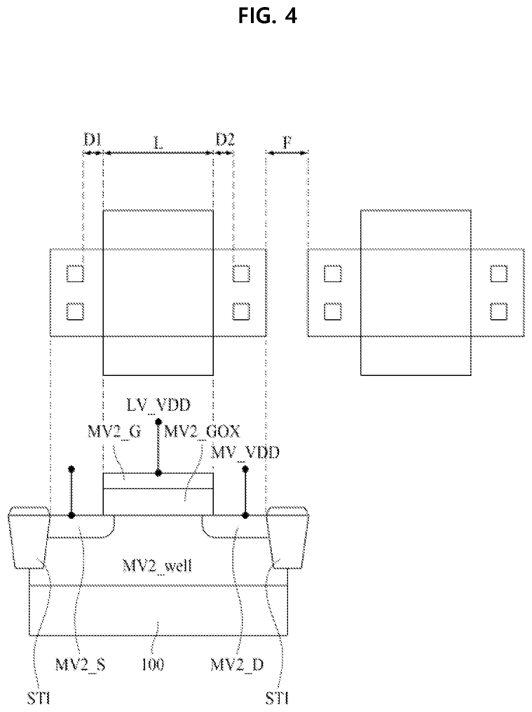

Hereinafter, a semiconductor device according to an embodiment of the present disclosure will be described in detail with reference to FIGS. 3 and 4.

FIG. 3 is a cross-sectional diagram of a low-voltage device and a first middle-voltage device according to an embodiment of the present disclosure, and FIG. 4 is a cross-sectional diagram of a second middle-voltage device according to an embodiment of the present disclosure.

Referring to FIG. 3, the semiconductor device according to an embodiment of the present disclosure may include a low-voltage device LV Device, a first middle-voltage device MV Device1, and a second middle-voltage device MV Device2, which may be stacked in or on a substrate 100.

The substrate 100 may include an elemental (i.e., having a single element) semiconductor, such as silicon, germanium, and/or other suitable materials, a compound semiconductor, such as silicon carbide, gallium arsenic, gallium phosphide, indium phosphide, indium arsenide, indium antimonide, and/or other suitable materials, and an alloy semiconductor, such as SiGe, GaAsP, AlInAs, AlGaAs, GaInAs, GaInP, GaInAsP, and/or other suitable materials. The substrate 100 may be a single-layer material having a uniform composition. Alternatively, the substrate 100 may include multiple material layers having similar or different compositions suitable for manufacture of an IC device. For example, the substrate 100 may be a silicon-on-insulator (SOI) substrate having a silicon layer formed on a silicon oxide layer. Alternatively, the substrate 100 may include a conductive layer, a semiconductor layer, a dielectric layer, other layers, or combinations thereof.

The substrate 100 includes various doped regions disposed in or on the substrate 100. The doped regions may be doped with n-type dopants, such as phosphorus or arsenic, and/or p-type dopants, such as boron or BF2, depending on design requirements. In addition, the doped regions may be formed directly on the substrate 100, in a p-well structure, in an n-well structure, in a dual-well structure, or in a raised structure. The doped regions may be formed by implantation of dopant atoms, in-situ doped epitaxial growth, and/or other suitable techniques.

According to an embodiment of the present disclosure, as shown in FIGS. 2 and 3, the substrate 100 includes a low-voltage well region LV_well, a 1-1^{st} middle-voltage well region MV1_well1, a 1-2^{nd} middle-voltage well region MV1_well2, a second middle-voltage well region MV2_well, a low-voltage drift region LV_LDD, a 1-1^{st} middle-voltage drift region MV1_LDD1, a 1-2^{nd} middle-voltage drift region MV1_LDD2, a low-voltage source region LV_S, a low-voltage drain region LV_D, a first middle-voltage source region MV1_S, a first middle-voltage drain region MV1_D, a second middle-voltage source region MV2_S, and a second middle-voltage drain region MV2_D, each of which is doped with an n-type or p-type dopant.

In addition, although not shown, the semiconductor device may further include a high-voltage device, and thus the substrate 100 may further include a high-voltage well, a high-voltage drift region, a high-voltage source region, and a high-voltage drain region.

The substrate 100 includes an isolation structure STI located in the substrate 100 in order to electrically isolate the devices from each other. To this end, the isolation structure STI may be located in each of regions between the devices to define a region in which each of the devices is disposed. The isolation structure STI may be a shallow trench isolation (STI) structure.

The isolation structure STI may include a dielectric material different from that of the substrate 100. The isolation structure STI may be, for example, silicon dioxide, silicon nitride, silicon carbide, silicon oxy-carbide, silicon oxy-nitride, another suitable dielectric material, or any combination thereof, or may be formed of a dielectric including the same.

The low-voltage device LV Device receives the first level voltage LV_VDD, and outputs a first output voltage according to the voltage input to a low-voltage gate electrode LV_G.

The low-voltage device LV Device includes a low-voltage well region LV_well, a low-voltage drift region LV_LDD, a low-voltage source region LV_S, and a low-voltage drain region LV_D, which are provided in the substrate 100, and includes a low-voltage gate dielectric layer LV_GOX and a low-voltage gate electrode LV_G, which are provided on the substrate 100.

The low-voltage well region LV_well, the low-voltage drift region LV_LDD, the low-voltage source region LV_S, and the low-voltage drain region LV_D may be formed by doping the substrate 100 with conductivity type impurities. That is, the low-voltage well region LV_well, the low-voltage drift region LV_LDD, the low-voltage source region LV_S, and the low-voltage drain region LV_D may be regions doped with n-type dopants or p-type dopants.

According to an embodiment of the present disclosure, the low-voltage well region LV_well may be doped with a first conductivity type impurity to a first well concentration. In this case, the first conductivity type impurity may be an n-type dopant or a p-type dopant.

The low-voltage drift region LV_LDD may be formed by implantation of a low-concentration impurity so as to be divided into a source-side low-voltage drift region and a drain-side low-voltage drift region, which are spaced apart from each other in the central region in the low-voltage well region LV_well. The low-voltage drift region LV_LDD may be doped with a second conductivity type impurity different from the first conductivity type impurity.

Each of the low-voltage source region LV_S and the low-voltage drain region LV_D may be formed by implanting a high-concentration impurity into the low-voltage drift region LV_LDD. In detail, the low-voltage source region LV_S may be formed by implanting a high-concentration impurity into the source-side low-voltage drift region, and the low-voltage drain region LV_D may be formed by implanting a high-concentration impurity into the drain-side low-voltage drift region. In this case, impurities having higher concentration than that implanted to form the low-voltage drift region LV_LDD may be implanted to form the low-voltage source region LV_S and the low-voltage drain region LV_D. The low-voltage source region LV_S and the low-voltage drain region LV_D may be doped with the second conductivity type impurities different from the first conductivity type impurity.

The low-voltage gate dielectric layer LV_GOX may be stacked on the substrate 100 so as to partially overlap the low-voltage drift region LV_LDD. In detail, the low-voltage gate dielectric layer LV_GOX may be stacked so as to partially overlap each of the source-side low-voltage drift region and the drain-side low-voltage drift region.

The low-voltage gate dielectric layer LV_GOX may be or include oxide (e.g., silicon oxide), nitride (e.g., silicon nitride), a high-k dielectric material, or the like. When the low-voltage gate dielectric layer LV_GOX is stacked through a high-k metal gate (HKMG) process, the low-voltage gate dielectric layer LV_GOX may be a high-k dielectric material. For example, the low-voltage gate dielectric layer LV_GOX may include a dielectric material including hafnium oxide, lanthanum oxide, other suitable materials, or combinations thereof. In addition, the low-voltage gate dielectric layer LV_GOX may be formed in a structure in which a plurality of layers is stacked, and the layers may be formed of materials having different dielectric constants.

The low-voltage gate electrode LV_G is stacked on the low-voltage gate dielectric layer LV_GOX. The low-voltage gate electrode LV_G may be or include, for example, titanium nitride, tantalum nitride, titanium, tantalum, tungsten, aluminum, copper, another suitable conductivity type metallic material, or any combination thereof. Alternatively, the low-voltage gate electrode LV_G may be or include polysilicon, intrinsic polysilicon, doped polysilicon, or any combination thereof. In addition, the low-voltage gate electrode LV_G may be formed in a structure in which a plurality of layers is stacked, and the layers may be formed of different conductivity type metallic materials.

In addition, although not shown, the low-voltage device LV Device may further include a diffusion barrier layer or a work-function layer. The diffusion barrier layer may be formed of titanium nitride (TiN), which may be doped (or undoped) with silicon. The work-function layer may determine work functions of the individual gates, and may include at least one layer or a plurality of layers formed of different materials.

The first middle-voltage device MV Device1 receives the second level voltage MV_VDD, and outputs a second output voltage according to the voltage input to a first middle-voltage gate electrode MV1_G. For example, the first middle-voltage device MV Device1 may be included in the level shifter circuit 230, as described above.

As shown in FIG. 3, the first middle-voltage device MV Device1 includes a 1-1^{st}middle-voltage well region MV1_well1, a 1-2^{nd} middle-voltage well region MV1_well2, a 1-1^{st}middle-voltage drift region MV1_LDD1, a 1-2^{nd} middle-voltage drift region MV1_LDD2, a first middle-voltage source region MV1_S, and a first middle-voltage drain region MV1_D, which are provided in the substrate 100, and includes a first middle-voltage gate dielectric layer MV1_GOX and a first middle-voltage gate electrode MV1_G, which are provided on the substrate 100.

The 1-1^{st} middle-voltage well region MV1_well1, the 1-2^{nd} middle-voltage well region MV1_well2, the 1-1^{st} middle-voltage drift region MV1_LDD1, the 1-2^{nd} middle-voltage drift region MV1_LDD2, the first middle-voltage source region MV1_S, and the first middle-voltage drain region MV1_D may be formed by doping the substrate 100 with conductivity type impurities. That is, the 1-1^{st} middle-voltage well region MV1_well1, the 1-2^{nd} middle-voltage well region MV1_well2, the 1-1^{st} middle-voltage drift region MV1_LDD1, the 1-2^{nd} middle-voltage drift region MV1_LDD2, the first middle-voltage source region MV1_S, and the first middle-voltage drain region MV1_D may be regions doped with n-type dopants or p-type dopants.

According to an embodiment of the present disclosure, the low-voltage well region LV_well and the 1-1^{st} middle-voltage well region MV1_well1 may be doped with the same conductivity type impurity to substantially the same concentration. That is, the low-voltage well region LV_well and the first middle-voltage well region MV1_well may be doped with the first conductivity type impurity to a first well concentration. For example, when the first middle-voltage device MV Device1 is an NMOS device, the first conductivity type impurity may be a p-type dopant, and the 1-1^{st} middle-voltage well region MV1_well1 and the 1-2^{nd} middle-voltage well region MV1_well2 may be p-wells doped with the p-type dopants. Meanwhile, when the first middle-voltage device MV Device1 is a PMOS device, the first conductivity type impurity may be an n-type dopant, and the 1-1^{st} middle-voltage well region MV1_well1 and the 1-2^{nd} middle-voltage well region MV1_well2 may be n-wells doped with the n-type dopants.

In addition, according to an embodiment of the present disclosure, the 1-1^{st} middle-voltage well region MV1_well1 and the 1-2^{nd} middle-voltage well region MV1_well2 may have different concentrations with respect to the conductivity type impurity. In detail, with respect to the center of the region in which the first middle-voltage device MV Device1 defined by the isolation structure STI in the substrate 100 is formed, one side may be doped with the first conductivity type impurity to a first well concentration, and the other side may be doped with the first conductivity type impurity to a second well concentration.

The 1-1^{st} middle-voltage drift region MV1_LDD1 and the 1-2^{nd} middle-voltage drift region MV1_LDD2 may be formed by implantation of low-concentration impurities so as to be spaced apart from each other in the central region in the low-voltage well region LV_well. According to an embodiment of the present disclosure, the 1-1^{st} middle-voltage drift region MV1_LDD1 is spaced apart from the edge of the region in which the first middle-voltage device MV Device1 is formed, and is located in the region spaced apart from the 1-2^{nd} middle-voltage drift region MV1_LDD2, as described above. In addition, the 1-1^{st} middle-voltage drift region MV1_LDD1 may be in contact with the first middle-voltage source region MV1_S, which will be described later, through a side surface thereof, and may be located at a shallower depth than the first middle-voltage source region MV1_S. Meanwhile, the 1-2^{nd} middle-voltage drift region MV1_LDD2 is adjacent to the edge of the region in which the first middle-voltage device MV Device1 is formed, and is formed in the region spaced apart from the 1-1^{st} middle-voltage drift region MV1_LDD1, as described above. In addition, the 1-2^{nd} middle-voltage drift region MV1_LDD2 may have a shape surrounding the lower surface and at least one side surface of the first middle-voltage drain region MV1_D.

The 1-1^{st} middle-voltage drift region MV1_LDD1 and the 1-2^{nd} middle-voltage drift region MV1_LDD2 may be doped with a conductivity type impurity different from that with which the 1-1^{st} middle-voltage well region MV1_well1 and the 1-2^{nd} middle-voltage well region MV1_well2 are doped. That is, the 1-1^{st} middle-voltage well region MV1_well1 and the 1-2^{nd} middle-voltage well region MV1_well2 may be doped with the first conductivity type impurity, and the 1-1^{st}middle-voltage drift region MV1_LDD1 and the 1-2^{nd} middle-voltage drift region MV1_LDD2 may be doped with the second conductivity type impurity different from the first conductivity type impurity.

The low-voltage drift region LV_LDD and the 1-1^{st} middle-voltage drift region MV1_LDD1 may have substantially the same concentration with respect to the second conductivity type impurity. The 1-1^{st} middle-voltage drift region MV1_LDD1 and the 1-2^{nd} middle-voltage drift region MV1_LDD2 may have a first drift concentration with respect to the second conductivity type impurity.

The first middle-voltage source region MV1_S and the first middle-voltage drain region MV1_D may be formed by implanting high-concentration impurities into the 1-1^{st} middle-voltage well region MV1_well1 or the 1-2^{nd} middle-voltage drift region MV1_LDD2. In detail, the first middle-voltage source region MV1_S may be formed by implantation of a high-concentration impurity at a position adjacent to an edge of the 1-1^{st} middle-voltage well region MV1_well1 between an edge of the region in which the first middle-voltage device MV Device1 is formed and the 1-1^{st} middle-voltage drift region MV1_LDD1, and the first middle-voltage drain region MV1_D may be formed by implanting a high-concentration impurity into the 1-2^{nd} middle-voltage drift region MV1_LDD2.

The first middle-voltage source region MV1_S and the first middle-voltage drain region MV1_D may be doped with a conductivity type impurity different from that with which the 1-1^{st} middle-voltage well region MV1_well1 and the 1-2^{nd} middle-voltage well region MV1_well2 are doped. That is, the 1-1^{st} middle-voltage well region MV1_well1 and the 1-2^{nd} middle-voltage well region MV1_well2 may be doped with the first conductivity type impurity, and the first middle-voltage source region MV1_S and the first middle-voltage drain region MV1_D may be doped with the second conductivity type impurity different from the first conductivity type impurity.

The first middle-voltage gate dielectric layer MV1_GOX may be stacked on the substrate 100 so as to partially overlap each of the 1-1^{st} middle-voltage drift region MV1_LDD1 and the 1-2^{nd} middle-voltage drift region MV1_LDD2.

The first middle-voltage gate dielectric layer MV1_GOX may be or include oxide (e.g., silicon oxide), nitride (e.g., silicon nitride), a high-k dielectric material, or the like. When the first middle-voltage gate dielectric layer MV1_GOX is stacked through a high-k metal gate (HKMG) process, the first middle-voltage gate dielectric layer MV1_GOX may be a high-k dielectric material. For example, the first middle-voltage gate dielectric layer MV1_GOX may include a dielectric material including hafnium oxide, lanthanum oxide, other suitable materials, or combinations thereof. In addition, the low-voltage gate dielectric layer LV_GOX may be formed in a structure in which a plurality of layers is stacked, and the layers may be formed of materials having different dielectric constants.

According to an embodiment of the present disclosure, the first middle-voltage gate dielectric layer MV1_GOX may be formed to have a smaller thickness than a second middle-voltage gate dielectric layer MV2_GOX, which will be described later. In detail, the first middle-voltage gate dielectric layer MV1_GOX may have a first thickness d1, and the second middle-voltage gate dielectric layer MV2_GOX may have a second thickness d2. In this case, the first thickness d1 is smaller than the second thickness d2 (d1<d2). For example, the first thickness d1 may be less than 100 Å, and the second thickness d2 may be greater than 100 Å.

Since the first middle-voltage gate dielectric layer MV1_GOX according to an embodiment of the present disclosure is formed to have a smaller thickness than the second middle-voltage gate dielectric layer MV2_GOX, the first middle-voltage device MV Device1 may have a lower threshold voltage than the second middle-voltage device MV Device2. Accordingly, even when a voltage lower than the second level voltage MV_VDD is applied to the first middle-voltage gate electrode MV1_G of the first middle-voltage device MV Device1, the first middle-voltage device MV Device1 may be driven, and the first middle-voltage device MV Device1 may have electrical characteristics required for a device constituting the level shifter circuit 230.

The first middle-voltage gate electrode MV1_G is stacked on the first middle-voltage gate dielectric layer MV1_GOX. The first middle-voltage gate electrode MV1_G may be formed of the same material as the low-voltage gate electrode LV_G.

The second middle-voltage device MV Device2 receives the second level voltage MV_VDD, and outputs a third output voltage according to the voltage input to a second middle-voltage gate electrode MV2_G. As described above, the second middle-voltage device MV Device2 may be included in the digital-to-analog converter circuit 240.

As shown in FIG. 4, the second middle-voltage device MV Device2 includes a second middle-voltage well region MV2_well1, a second middle-voltage source region MV2_S, and a second middle-voltage drain region MV2_D, which are provided in the substrate 100, and includes a second middle-voltage gate dielectric layer MV2_GOX and a second middle-voltage gate electrode MV2_G, which are provided on the substrate 100.

The second middle-voltage well region MV2_well, the second middle-voltage source region MV2_S, and the second middle-voltage drain region MV2_D may be formed by doping the substrate 100 with conductivity type impurities. That is, the second middle-voltage well region MV2_well, the second middle-voltage source region MV2_S, and the second middle-voltage drain region MV2_D may be regions doped with n-type dopants or p-type dopants.

According to an embodiment of the present disclosure, the second middle-voltage well region MV2_well may be formed of substantially the same material as the 1-2^{nd} middle-voltage well region MV1_well2. That is, the 1-2^{nd} middle-voltage well region MV1_well2 and the second middle-voltage well region MV2_well may be doped with the first conductivity type impurity. For example, when the second middle-voltage device MV Device2 is an NMOS device, the first conductivity type impurity may be a p-type dopant, and the second middle-voltage well region MV2_well may be a p-well doped with the p-type dopant. Meanwhile, when the second middle-voltage device MV Device2 is a PMOS device, the first conductivity type impurity is an n-type dopant, and accordingly, the 1-1^{st} middle-voltage well region MV1_well1 and the 1-2^{nd} middle-voltage well region MV1_well2 may be n-wells doped with the n-type dopants.

In addition, according to an embodiment of the present disclosure, the second middle-voltage well region MV2_well may have substantially the same concentration as the 1-2^{nd} middle-voltage well region MV1_well2, and may have a different concentration from the low-voltage well region LV_well and the 1-1^{st} middle-voltage well region MV1_well1. That is, the low-voltage well region LV_well and the 1-1^{st} middle-voltage well region MV1_well1 may have a first well concentration, and the 1-2^{nd} middle-voltage well region MV1_well2 and the second middle-voltage well region MV2_well may have a second well concentration different from the first well concentration.

According to an embodiment of the present disclosure, the second middle-voltage device MV Device2 does not include a drift region. Accordingly, a resistance between the second middle-voltage source region MV2_S and the second middle-voltage drain region MV2_D is reduced, and thus the amount of current flowing between the second middle-voltage source region MV2_S and the second middle-voltage drain region MV2_D is increased. Therefore, as shown in FIG. 4, a gap D1 between a contact region of the second middle-voltage source region MV2_S and the second middle-voltage gate electrode MV2_G, a gap D2 between a contact region of the second middle-voltage drain region MV2_D and the second middle-voltage gate electrode MV2_G, a width L of the second middle-voltage gate electrode MV2_G, and a gap F from another second middle-voltage device MV Device2 may be reduced. As a result, the area of the second middle-voltage device MV Device2 may be reduced. The second middle-voltage device MV Device2 according to an embodiment of the present disclosure may have electrical characteristics required for a device constituting the digital-to-analog converter circuit 240.

The second middle-voltage source region MV2_S and the second middle-voltage drain region MV2_D may be formed by implanting high-concentration impurities into the second middle-voltage well region MV2_well. In detail, the second middle-voltage source region MV2_S and the second middle-voltage drain region MV2_D may be formed by implantation of high-concentration impurities so as to be spaced apart from each other in the central region in the second middle-voltage well region MV2_well.

The second middle-voltage gate dielectric layer MV2_GOX may be stacked on the substrate 100 so as to partially overlap each of the second middle-voltage source region MV2_S and the second middle-voltage drain region MV2_D.

The second middle-voltage gate dielectric layer MV2_GOX may be or include oxide (e.g., silicon oxide), nitride (e.g., silicon nitride), a high-k dielectric material, or the like. When the second middle-voltage gate dielectric layer MV2_GOX is stacked through a high-k metal gate (HKMG) process, the second middle-voltage gate dielectric layer MV2_GOX may be a high-k dielectric material. For example, the second middle-voltage gate dielectric layer MV2_GOX may include a dielectric material including hafnium oxide, lanthanum oxide, other suitable materials, or combinations thereof. In addition, the second middle-voltage gate dielectric layer MV2_GOX may be formed in a structure in which a plurality of layers is stacked, and the layers may be formed of materials having different dielectric constants.

According to an embodiment of the present disclosure, the second middle-voltage gate dielectric layer MV2_GOX may be formed to have a larger thickness than the first middle-voltage gate dielectric layer MV1_GOX. In detail, the first middle-voltage gate dielectric layer MV1_GOX may have a first thickness d1, and the second middle-voltage gate dielectric layer MV2_GOX may have a second thickness d2. In this case, the second thickness d2 is larger than the first thickness d1 (d1<d2). For example, the second thickness d2 may be greater than 100 Å, and the first thickness d1 may be less than 100 Å.

The second middle-voltage gate electrode MV2_G is stacked on the second middle-voltage gate dielectric layer MV2_GOX. The second middle-voltage gate electrode MV2_G may be formed of the same material as the low-voltage gate electrode LV_G and the first middle-voltage gate electrode MV1_G.

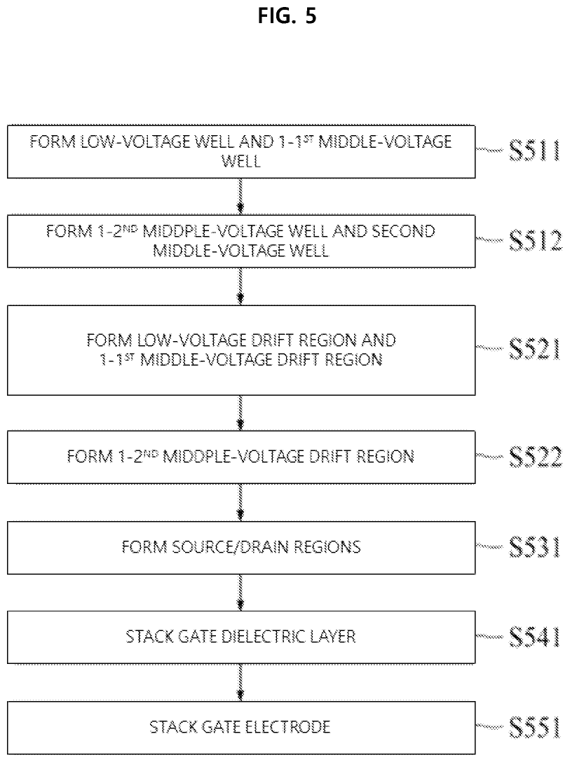

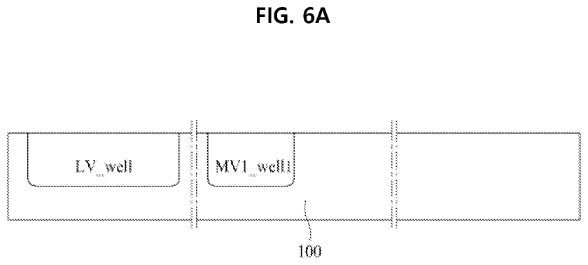

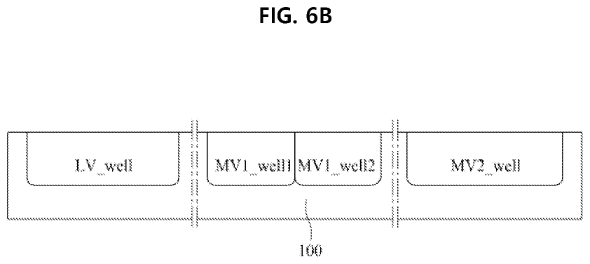

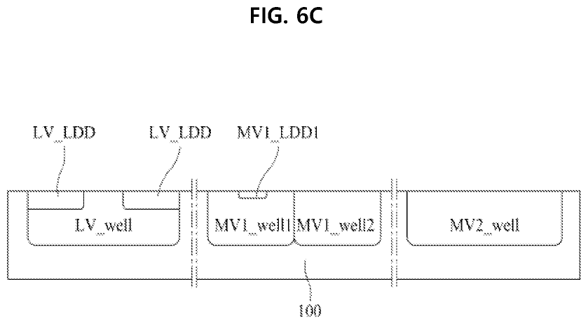

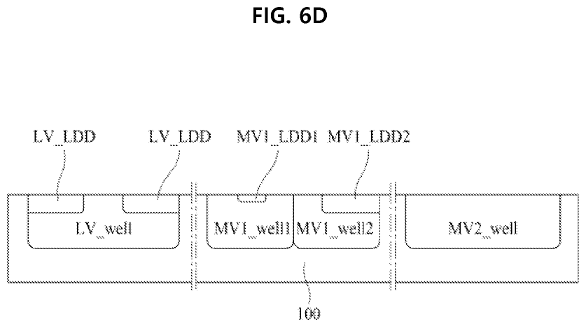

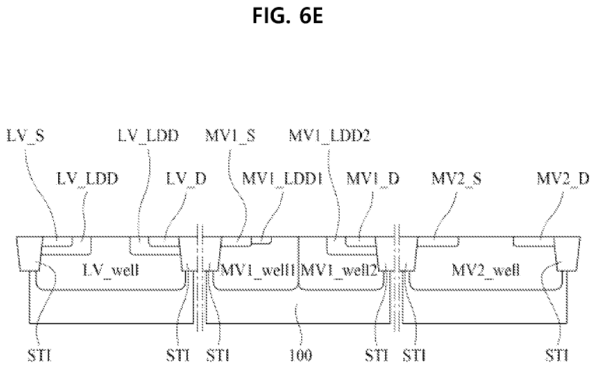

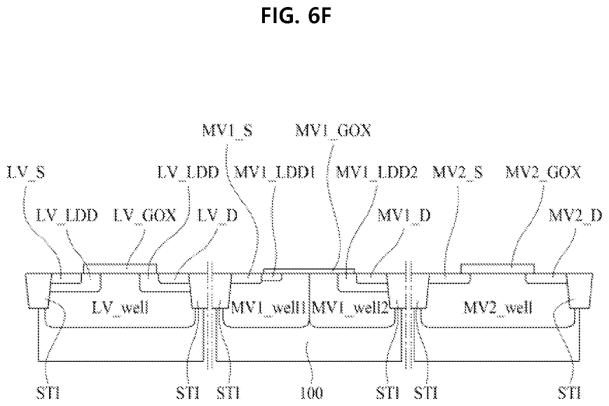

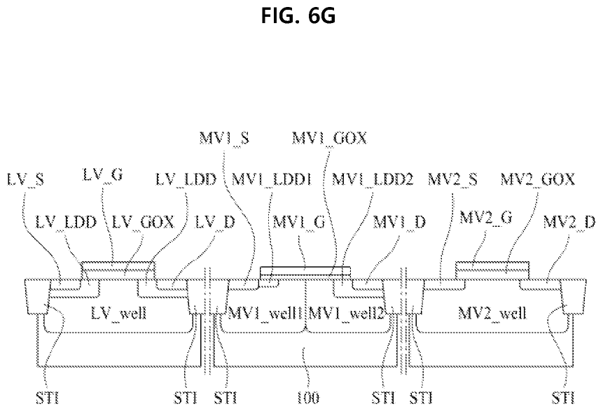

A method of manufacturing a semiconductor device according to an embodiment of the present disclosure will be described in detail with reference to FIGS. 5 to 6G.

FIG. 5 is a flowchart of a semiconductor device manufacturing process according to an embodiment of the present disclosure, and FIGS. 6A to 6G are diagrams showing a semiconductor device manufacturing process according to an embodiment of the present disclosure.

Referring to FIG. 5, first, a low-voltage well region LV_well and a 1-1^{st} middle-voltage well region MV1_well1 are formed on a substrate 100 (S511). In detail, as shown in FIG. 6A, a region of the substrate 100 in which a low-voltage device LV Device is to be formed and one side with respect to the center of a region of the substrate 100 in which a first middle-voltage device MV Device1 is to be formed are doped with n-type or p-type dopants to form the low-voltage well region LV_well and the 1-1^{st} middle-voltage well region MV1_well1. In this case, the low-voltage well region LV_well and the 1-1^{st} middle-voltage well region MV1_well1 may be formed through an ion implantation process using a mask. According to an embodiment of the present disclosure, since the low-voltage well region LV_well and the 1-1^{st} middle-voltage well region MV1_well1 are formed using one mask, separate masks for respectively forming these well regions are not needed, and thus manufacturing costs of the semiconductor device may be reduced.

In addition, according to an embodiment of the present disclosure, the low-voltage well region LV_well and the 1-1^{st} middle-voltage well region MV1_well1 may be doped with the same conductivity type impurity to substantially the same concentration. That is, the low-voltage well region LV_well and the first middle-voltage well region MV1_well may be doped with a first conductivity type impurity to a first well concentration.

Thereafter, a 1-2^{nd} middle-voltage well region MV1_well2 and a second middle-voltage well region MV2_well are formed on the substrate 100 (S512). In detail, as shown in FIG. 6B, the other side with respect to the center of the region of the substrate 100 in which the first middle-voltage device MV Device1 is to be formed and a region of the substrate 100 in which a second middle-voltage device MV Device2 is to be formed are doped with n-type or p-type dopants to form the 1-2^{nd} middle-voltage well region MV1_well2 and the second middle-voltage well region MV2_well. In this case, the 1-2^{nd} middle-voltage well region MV1_well2 and the second middle-voltage well region MV2_well may be formed through an ion implantation process using a mask. According to an embodiment of the present disclosure, since the 1-2^{nd} middle-voltage well region MV1_well2 and the second middle-voltage well region MV2_well are formed using one mask, separate masks for respectively forming these well regions are not needed, and thus manufacturing costs of the semiconductor device may be reduced.

According to an embodiment of the present disclosure, the 1-1^{st} middle-voltage well region MV1_well1 and the 1-2^{nd} middle-voltage well region MV1_well2 may have different concentrations with respect to the conductivity type impurity. In detail, with respect to the center of the region in which the first middle-voltage device MV Device1 defined by the isolation structure STI in the substrate 100 is formed, one side may be doped with the first conductivity type impurity to the first well concentration, and the other side may be doped with the first conductivity type impurity to a second well concentration different from the first well concentration.

In addition, according to an embodiment of the present disclosure, the 1-2^{nd} middle-voltage well region MV1_well2 and the second middle-voltage well region MV2_well may be doped with the same conductivity type impurity to substantially the same concentration. That is, the 1-2^{nd} middle-voltage well region MV1_well2 and the second middle-voltage well region MV2_well may be doped with the first conductivity type impurity to the second well concentration.

Accordingly, the low-voltage well region LV_well and the 1-1^{st} middle-voltage well region MV1_well1 may be doped with the first conductivity type impurity to the first well concentration, and the 1-2^{nd} middle-voltage well region MV1_well2 and the second middle-voltage well region MV2_well may be doped with the first conductivity type impurity to the second well concentration.

Although it is illustrated in the drawings that, after the low-voltage well region LV_well and the 1-1^{st} middle-voltage well region MV1_well1 are formed, the 1-2^{nd} middle-voltage well region MV1_well2 and the second middle-voltage well region MV2_well are formed, the process order is not limited thereto. After the 1-2^{nd} middle-voltage well region MV1_well2 and the second middle-voltage well region MV2_well are formed, the low-voltage well region LV_well and the 1-1^{st} middle-voltage well region MV1_well1 may be formed.

Thereafter, a low-voltage drift region LV_LDD and a 1-1^{st} middle-voltage drift region MV1_LDD1 are formed on the substrate 100 (S521). In detail, the low-voltage drift region LV_LDD may be formed by implantation of a low-concentration impurity so as to be divided into a source-side low-voltage drift region and a drain-side low-voltage drift region, which are spaced apart from each other in the central region in the low-voltage well region LV_well. The 1-1^{st} middle-voltage drift region MV1_LDD1 may be formed at a position spaced apart from the edge of the region of the substrate 100 in which the first middle-voltage device MV Device1 is to be formed by a region in which a first middle-voltage source region MV1_S is to be formed. According to an embodiment of the present disclosure, since the low-voltage drift region LV_LDD and the 1-1^{st} middle-voltage drift region MV1_LDD1 are formed using one mask, separate masks for respectively forming these drift regions are not needed, and thus manufacturing costs of the semiconductor device may be reduced.

The low-voltage drift region LV_LDD and the 1-1^{st} middle-voltage drift region MV1_LDD1 may be doped with a conductivity type impurity different from that with which the low-voltage well region LV_well and the 1-1^{st} middle-voltage well region MV1_well1 are doped. That is, the low-voltage drift region LV_LDD and the 1-1^{st} middle-voltage drift region MV1_LDD1 may be doped with the second conductivity type impurity different from the first conductivity type impurity.

The low-voltage drift region LV_LDD and the 1-1^{st} middle-voltage drift region MV1_LDD1 may have the same concentration with respect to the second conductivity type impurity. That is, the low-voltage drift region LV_LDD and the 1-1^{st} middle-voltage drift region MV1_LDD1 may have a first drift concentration with respect to the second conductivity type impurity.

Thereafter, a 1-2^{nd} middle-voltage drift region MV1_LDD2 is formed on the substrate 100 (S522). In detail, the 1-2^{nd} middle-voltage drift region MV1_LDD2 may be formed by implantation of a low-concentration impurity at an edge of the region in which the first middle-voltage device MV Device1 is to be formed, opposite the 1-1^{st} middle-voltage drift region MV1_LDD1.

The 1-2^{nd} middle-voltage drift region MV1_LDD2 may be doped with a conductivity type impurity different from that with which the low-voltage well region LV_well and the 1-1^{st} middle-voltage well region MV1_well1 are doped. That is, the low-voltage well region LV_well and the 1-1^{st} middle-voltage well region MV1_well1 may be doped with the first conductivity type impurity, and the 1-2^{nd} middle-voltage drift region MV1_LDD2 may be doped with the second conductivity type impurity different from the first conductivity type impurity.

In addition, the 1-2^{nd} middle-voltage drift region MV1_LDD2 may have a different concentration with respect to the second conductivity type impurity from the low-voltage drift region LV_LDD and the 1-1^{st} middle-voltage drift region MV1_LDD1. That is, the low-voltage drift region LV_LDD and the 1-1^{st} middle-voltage drift region MV1_LDD1 may have a first drift concentration with respect to the second conductivity type impurity, and the 1-2^{nd} middle-voltage drift region MV1_LDD2 may have a second drift concentration with respect to the second conductivity type impurity.

According to an embodiment of the present disclosure, the second middle-voltage device MV Device2 does not include a drift region. Accordingly, a resistance between the second middle-voltage source region MV2_S and the second middle-voltage drain region MV2_D is reduced, and thus the amount of current flowing between the second middle-voltage source region MV2_S and the second middle-voltage drain region MV2_D is increased. Therefore, as shown in FIG. 4, a gap D1 between a contact region of the second middle-voltage source region MV2_S and the second middle-voltage gate electrode MV2_G, a gap D2 between a contact region of the second middle-voltage drain region MV2_D and the second middle-voltage gate electrode MV2_G, a width L of the second middle-voltage gate electrode MV2_G, and a gap F from another second middle-voltage device MV Device2 may be reduced. As a result, the area of the second middle-voltage device MV Device2 may be reduced. The second middle-voltage device MV Device2 according to an embodiment of the present disclosure may have electrical characteristics required for a device constituting the digital-to-analog converter circuit 240.

Although it is illustrated in the drawings that, after the low-voltage drift region LV_LDD and the 1-1^{st}middle-voltage drift region MV1_LDD1 are formed, the 1-2^{nd} middle-voltage drift region MV1_LDD2 is formed, the process order is not limited thereto. After the 1-2^{nd} middle-voltage drift region MV1_LDD2 is formed, the low-voltage drift region LV_LDD and the 1-1^{st} middle-voltage drift region MV1_LDD1 may be formed.

Thereafter, source regions and drain regions of the low-voltage device LV Device, the first middle-voltage device MV Device1, and the second middle-voltage device MV Device2 are formed (S531). In detail, a low-voltage source region LV_S, a low-voltage drain region LV_D, a first middle-voltage source region MV1_S, a first middle-voltage drain region MV1_D, a second middle-voltage source region MV2_S, and a second middle-voltage drain region MV2_D are formed by implantation of the second conductivity type impurity. Each of the low-voltage source region LV_S and the low-voltage drain region LV_D is formed by implanting the second conductivity type impurity of high concentration into the low-voltage drift region LV_LDD. The first middle-voltage source region MV1_S is formed by implanting the second conductivity type impurity of high concentration into the 1-1^{st} middle-voltage well region MV1_well1 between an edge of the region in which the first middle-voltage device MV Device1 is to be formed and the 1-1^{st} middle-voltage drift region MV1_LDD1. The first middle-voltage drain region MV1_D is formed by implanting a high-concentration impurity into the 1-2^{nd} middle-voltage drift region MV1_LDD2. The second middle-voltage source region MV2_S and the second middle-voltage drain region MV2_D are formed by implanting the second conductivity type impurity of high concentration into the second middle-voltage well region MV2_well. In this case, the low-voltage source region LV_S, the low-voltage drain region LV_D, the first middle-voltage source region MV1_S, the first middle-voltage drain region MV1_D, the second middle-voltage source region MV2_S, and the second middle-voltage drain region MV2_D may be formed by implantation of the conductivity type impurities using respective masks.

Thereafter, gate dielectric layers of the low-voltage device LV Device, the first middle-voltage device MV Device1, and the second middle-voltage device MV Device2 are stacked (S541). In detail, the low-voltage gate dielectric layer LV_GOX is stacked on the substrate 100 so as to partially overlap the low-voltage drift region LV_LDD, the first middle-voltage gate dielectric layer MV1_GOX is stacked on the substrate 100 so as to partially overlap each of the 1-1^{st} middle-voltage drift region MV1_LDD1 and the 1-2^{nd} middle-voltage drift region MV1_LDD2, and the second middle-voltage gate dielectric layer MV2_GOX is stacked on the substrate 100 so as to partially overlap the second middle-voltage source region MV2_S and the second middle-voltage drain region MV2_D.

According to an embodiment of the present disclosure, the first middle-voltage gate dielectric layer MV1_GOX may be formed to have a smaller thickness than the second middle-voltage gate dielectric layer MV2_GOX. In detail, the first middle-voltage gate dielectric layer MV1_GOX may have a first thickness d1, and the second middle-voltage gate dielectric layer MV2_GOX may have a second thickness d2. In this case, the first thickness d1 is smaller than the second thickness d2 (d1<d2). For example, the first thickness d1 may be less than 100 Å, and the second thickness d2 may be greater than 100 Å. Accordingly, the first middle-voltage device MV Device1 may have a lower threshold voltage than the second middle-voltage device MV Device2. Even when a voltage lower than the second level voltage MV_VDD is applied to the first middle-voltage gate electrode MV1_G, the first middle-voltage device MV Device1 may be driven, and the first middle-voltage device MV Device1 may function as a device constituting the level shifter circuit 230. That is, the first middle-voltage device MV Device1 according to an embodiment of the present disclosure may have electrical characteristics suitable for the circuit (e.g., level shifter circuit 230) constituted by the first middle-voltage device MV Device1.

Thereafter, gate electrodes of the low-voltage device LV Device, the first middle-voltage device MV Device1, and the second middle-voltage device MV Device2 are stacked (S551). In detail, the low-voltage gate electrode LV_G is stacked on the low-voltage gate dielectric layer LV_GOX, the first middle-voltage gate electrode MV1_G is stacked on the first middle-voltage gate dielectric layer MV1_GOX, and the second middle-voltage gate electrode MV2_G is stacked on the second middle-voltage gate dielectric layer MV2_GOX.

As is apparent from the above description, a semiconductor device, a display driving device including the same, and a method of manufacturing the semiconductor device according to the present disclosure may implement electrical characteristics of devices, and may reduce manufacturing costs of the semiconductor device.

While the present disclosure has been particularly shown and described with reference to exemplary embodiments thereof, these embodiments are only proposed for illustrative purposes, and it will be apparent to those skilled in the art that various changes in form and details may be made without departing from the essential characteristics of the present disclosure.

Therefore, the exemplary embodiments should be considered in a descriptive sense only and not for purposes of limitation. The scope of the disclosure is defined not by the detailed description of the disclosure but by the appended claims, and encompasses all modifications and equivalents that fall within the scope of the appended claims.

What is claimed is:

1. A semiconductor device comprising:
a low-voltage device configured to receive a first level voltage; and
a first middle-voltage device configured to receive a second level voltage higher than the first level voltage,
wherein the low-voltage device comprises a low-voltage well region,
wherein the first middle-voltage device comprises a 1-1^{st} middle-voltage well region and a 1-2^{nd} middle-voltage well region, and
wherein the low-voltage well region and the 1-1^{st} middle-voltage well region have a first well concentration with respect to a first conductivity type impurity.

2. The semiconductor device according to claim 1, wherein the 1-2^{nd} middle-voltage well region has a second well concentration different from the first well concentration with respect to the first conductivity type impurity.

3. The semiconductor device according to claim 1, further comprising a second middle-voltage device configured to receive the second level voltage and to output a third output voltage according to a voltage applied to a second middle-voltage gate electrode,
wherein the second middle-voltage device comprises a second middle-voltage well region, and
wherein the 1-2^{nd} middle-voltage well region and the second middle-voltage well region have a second well concentration different from the first well concentration with respect to the first conductivity type impurity.

4. The semiconductor device according to claim 1, wherein the low-voltage device further comprises a low-voltage drift region,
wherein the first middle-voltage device further comprises a 1-1^{st} middle-voltage drift region and a 1-2^{nd} middle-voltage drift region,
wherein the low-voltage drift region and the 1-1^{st} middle-voltage drift region have a first drift concentration with respect to a second conductivity type impurity different from the first conductivity type impurity, and
wherein the 1-2^{nd} middle-voltage drift region has a second drift concentration with respect to the second conductivity type impurity.

5. The semiconductor device according to claim 4, wherein the first middle-voltage device further comprises a first middle-voltage source region and a first middle-voltage drain region,
wherein the 1-1^{st} middle-voltage drift region has a side surface contacting the first middle-voltage source region, and
wherein the 1-2^{nd} middle-voltage drift region surrounds a lower surface and at least one side surface of the first middle-voltage drain region.

6. The semiconductor device according to claim 1, further comprising a second middle-voltage device configured to receive the second level voltage,
wherein the first middle-voltage device further comprises a first middle-voltage gate dielectric layer having a first thickness, and
wherein the second middle-voltage device further comprises a second middle-voltage gate dielectric layer having a second thickness larger than the first thickness.

7. The semiconductor device according to claim 1, further comprising a second middle-voltage device configured to receive the second level voltage,
wherein the second middle-voltage device comprises a second middle-voltage source region, a second middle-voltage drain region, and a second middle-voltage gate dielectric layer located on the second middle-voltage source region and the second middle-voltage drain region, and
wherein the second middle-voltage gate dielectric layer overlaps a portion of the second middle-voltage source region and a portion of the second middle-voltage drain region.

8. A display driving device comprising:
a low-voltage device configured to receive a first level voltage; and
a first middle-voltage device configured to receive a second level voltage higher than the first level voltage,
wherein the low-voltage device comprises a low-voltage well region,
wherein the first middle-voltage device comprises a 1-1^{st} middle-voltage well region and a 1-2^{nd} middle-voltage well region, and
wherein the low-voltage well region and the 1-1^{st} middle-voltage well region have a first well concentration with respect to a first conductivity type impurity.

9. The display driving device according to claim 8, wherein the 1-2^{nd} middle-voltage well region has a second well concentration different from the first well concentration with respect to the first conductivity type impurity.

10. The display driving device according to claim 8, further comprising a second middle-voltage device configured to receive the second level voltage and to output a third output voltage according to a voltage applied to a second middle-voltage gate electrode,
wherein the second middle-voltage device comprises a second middle-voltage well region, and
wherein the 1-2^{nd} middle-voltage well region and the second middle-voltage well region have a second well concentration different from the first well concentration with respect to the first conductivity type impurity.

11. The display driving device according to claim 8, wherein the low-voltage device further comprises a low-voltage drift region,
wherein the first middle-voltage device further comprises a 1-1^{st} middle-voltage drift region and a 1-2^{nd} middle-voltage drift region,
wherein the low-voltage drift region and the 1-1^{st} middle-voltage drift region have a first drift concentration with respect to a second conductivity type impurity different from the first conductivity type impurity, and
wherein the 1-2^{nd} middle-voltage drift region has a second drift concentration with respect to the second conductivity type impurity.

12. The display driving device according to claim 11, wherein the first middle-voltage device further comprises a first middle-voltage source region and a first middle-voltage drain region,
wherein the 1-1^{st} middle-voltage drift region has a side surface contacting the first middle-voltage source region, and
wherein the 1-2^{nd} middle-voltage drift region surrounds a lower surface and at least one side surface of the first middle-voltage drain region.

13. The display driving device according to claim 8, further comprising a second middle-voltage device configured to receive the second level voltage,
wherein the first middle-voltage device further comprises a first middle-voltage gate dielectric layer having a first thickness, and
wherein the second middle-voltage device further comprises a second middle-voltage gate dielectric layer having a second thickness larger than the first thickness.

14. The display driving device according to claim 8, further comprising a second middle-voltage device configured to receive the second level voltage,
wherein the second middle-voltage device comprises a second middle-voltage source region, a second middle-voltage drain region, and a second middle-voltage gate dielectric layer located on the second middle-voltage source region and the second middle-voltage drain region, and
wherein the second middle-voltage gate dielectric layer overlaps a portion of the second middle-voltage source region and a portion of the second middle-voltage drain region.

15. A method of manufacturing a semiconductor device, the method comprising:
forming a low-voltage well region and a 1-1^{st} middle-voltage well region;
forming a 1-2^{nd} middle-voltage well region and a second middle-voltage well region;
forming a low-voltage drift region and a 1-1^{st} middle-voltage drift region;
forming a 1-2^{nd} middle-voltage drift region;
forming a source region and a drain region; and
forming a gate dielectric layer.

16. The method according to claim 15, wherein, in the forming a low-voltage well region and a 1-1^{st}middle-voltage well region, the low-voltage well region and the 1-1^{st} middle-voltage well region are formed by doping a substrate with a first conductivity type impurity to a first well concentration using a first mask, and
wherein, in the forming a 1-2^{nd} middle-voltage well region and a second middle-voltage well region, the 1-2^{nd} middle-voltage well region and the second middle-voltage well region are formed by doping the substrate with the first conductivity type impurity to a second well concentration different from the first well concentration using a second mask.

17. The method according to claim 15, wherein, in the forming a low-voltage drift region and a 1-1^{st}middle-voltage drift region, the low-voltage drift region and the 1-1^{st} middle-voltage drift region are formed by doping a substrate with a second conductivity type impurity to a first drift concentration using a third mask, and
wherein, in the forming a 1-2^{nd} middle-voltage drift region, the 1-2^{nd} middle-voltage drift region is formed by doping the substrate with the second conductivity type impurity to a second drift concentration using a fourth mask.

18. The method according to claim 15, wherein, in the forming a source region and a drain region, a low-voltage source region, a low-voltage drain region, a first middle-voltage source region, a first middle-voltage drain region, a second middle-voltage source region, and a second middle-voltage drain region are formed,
wherein each of the low-voltage source region and the low-voltage drain region is formed in the low-voltage drift region,
wherein the first middle-voltage source region is formed in the 1-1^{st} middle-voltage well region, and the first middle-voltage drain region is formed in the 1-2^{nd} middle-voltage drift region, and
wherein the second middle-voltage source region and the second middle-voltage drain region are formed in the second middle-voltage well region.

19. The method according to claim 15, wherein, in the forming a gate dielectric layer, a first middle-voltage dielectric layer is formed to a first thickness, and a second middle-voltage dielectric layer is formed to a second thickness larger than the first thickness.
